(19) United States
(12) Patent Application Publication
(10) Pub. No.: US 2009/0008657 A1
(43) Pub. Date: Jan. 8, 2009

(54) Semiconductor light-emitting device with low-density defects and method of fabricating the same

(75) Inventor: Wei-Kai Wang, Shengang Township (TW)

Correspondence Address: BIRCH STEWART KOLASCH & BIRCH, PO BOX 747, FALLS CHURCH, VA, 22040-0747, US

(73) Assignee: HUGA OPTOTECH INC.

(21) Appl. No.: 11/987,646

(22) Filed: Dec. 3, 2007

(30) Foreign Application Priority Data
Jul. 6, 2007 (TW) 096124702

(51) Int. Cl. H01L 33/00

(52) U.S. Cl. 257/94; 438/47; 257/E33.006; 257/E33.014

(57) ABSTRACT

A semiconductor light-emitting device and a method of fabricating the same are provided. The semiconductor light-emitting device includes a substrate, a multi-layer structure and an ohmic electrode structure. The substrate has a first upper surface and a plurality of first recesses formed in the first upper surface. The multi-layer structure is formed on the first upper surface of the substrate and includes a light-emitting region. A bottom-most layer of the multi-layer structure is formed on the first upper surface of the substrate. The bottom-most layer has a second upper surface and a plurality of second recesses formed in the second upper surface. The second recesses project on the first upper surface. The ohmic electrode structure is formed on the multi-layer structure.

### BACKGROUND OF THE INVENTION

1. Field of the Invention

The present invention relates to a semiconductor light-emitting device and, more particularly, to a semiconductor light-emitting device with low-density inner defects.

2. Description of the Prior Art

The current semiconductor light-emitting devices, such as light-emitting diodes, have been used for a wide variety of applications, e.g. illumination, remote control. To ensure high functional reliability as great as possible and a low power requirement of the semiconductor light-emitting devices, the external quantum efficiency is required for the devices.

In theory, the external quantum efficiency of a semiconductor light-emitting device is determined by the internal quantum efficiency thereof. The internal quantum efficiency is determined by the material property and quality. If a density of inner defects of the semiconductor light-emitting device becomes higher, it will lower the internal quantum efficiency and light-extraction efficiency of the semiconductor light-emitting device.

Please refer to FIG. 1A. FIG. 1A is a schematic diagram of the distribution of defects inside a semiconductor light-emitting device 1. In general condition, after the epitaxy is performed on a substrate 10, the inner defects 120 of the semiconductor light-emitting device 1 will extend upward and affect the material property of the semiconductor light-emitting device 1, which lowers the internal quantum efficiency.

Please refer to FIG. 1B. FIG. 1B is a schematic diagram of using an oxide layer 14 (e.g. SiO₂) to improve the defects 120 inside the semiconductor light-emitting device 1 in the prior art. As shown in FIG. 1B, the formation of the oxide layer 14 can prohibit the inner defects 120 from extending upward. Because it is not easy for a semiconductor material layer 12 (e.g. GaN) to grow on the oxide layer 14, lateral epitaxy occurs as shown in FIG. 1B.

However, the manufacturing process will be contaminated due to the formation of the oxide layer 14. In addition, after the oxide layer 14 is deposited and selectively etched, the oxide layer 14 easily remains on the surface on which the semiconductor material layer 12 will be deposited. Because it is not easy for the semiconductor material layer 12 to grow on the oxide layer 14, after the semiconductor material layer 12 is deposited, the surface of the semiconductor material layer 12 will exhibit many pits, i.e. surface haze. This condition will deteriorate the material property of the semiconductor light-emitting device 1.

Therefore, the main scope of the invention is to provide a semiconductor light-emitting device with low-density inner defects to enhance the internal quantum efficiency and light-extraction efficiency of the semiconductor light-emitting device.

### SUMMARY OF THE INVENTION

One scope of the invention is to provide a semiconductor light-emitting device and a method of fabricating the same.

According to an embodiment of the invention, the semiconductor light-emitting device includes a substrate, a multi-layer structure, and an ohmic electrode structure. The substrate has a first upper surface and a plurality of first recesses formed on the first upper surface. The multi-layer structure is formed on the first upper surface of the substrate and includes a light-emitting region. A bottom-most layer of the multi-layer structure is formed on the first upper surface of the substrate and has a second upper surface and a plurality of second recesses. The plurality of second recesses are formed on the second upper surface and project on the first upper surface of the substrate. The ohmic electrode structure is formed on the multi-layer structure.

According to another embodiment of the invention, it is related to a method of fabricating a semiconductor light-emitting device.

First, the method prepares a substrate. Subsequently, the method applies a first selective etching process on a first upper surface of the substrate such that a plurality of first recesses are formed on the first upper surface. Then, the method forms a bottom-most layer of a multi-layer structure on the first upper surface of the substrate. Subsequently, the method applies a second selective etching process on a second upper surface of the bottom-most layer such that a plurality of second recesses are formed on the second upper surface. The plurality of second recesses project onto the first upper surface of the substrate. Next, the method forms other layers of the multi-layer structure on the second upper surface of the bottom-most layer. The multi-layer structure includes a light-emitting region. Finally, the method forms an ohmic electrode structure on the multi-layer structure to finish the semiconductor light-emitting device.

Compared to the prior art, the semiconductor light-emitting device according to the invention can have a semiconductor material layer with defects in low density, and the epitaxy of the semiconductor light-emitting device is to be performed on the semiconductor material layer. Thereby, the internal quantum efficiency and light-extraction efficiency of the semiconductor light-emitting device are enhanced. In addition, there is no contamination generated during the manufacturing process of the semiconductor light-emitting device according to the invention. Also, no haze phenomenon occurs on the surface of the semiconductor material layer.

The advantage and spirit of the invention may be understood by the following recitations together with the appended drawings.

### BRIEF DESCRIPTION OF THE APPENDED DRAWINGS

FIG. 1A is a schematic diagram of the distribution of defects inside a semiconductor light-emitting device.

FIG. 1B is a schematic diagram of using an oxide layer to improve the defects inside a semiconductor light-emitting device in the prior art.

FIG. 2 is a sectional view of a semiconductor light-emitting device according to an embodiment of the invention.

FIG. 3 is a projection view of the first recesses and the second recesses on the first upper surface of the substrate.

The figures from FIG. 4A to FIG. 4F are the sectional views illustrating a method of fabricating a semiconductor light-emitting device according to another embodiment of the invention.

FIG. 5A and FIG. 5B show the densities of inner defects of an ordinary semiconductor light-emitting device and a semiconductor light-emitting device according to the invention, respectively.

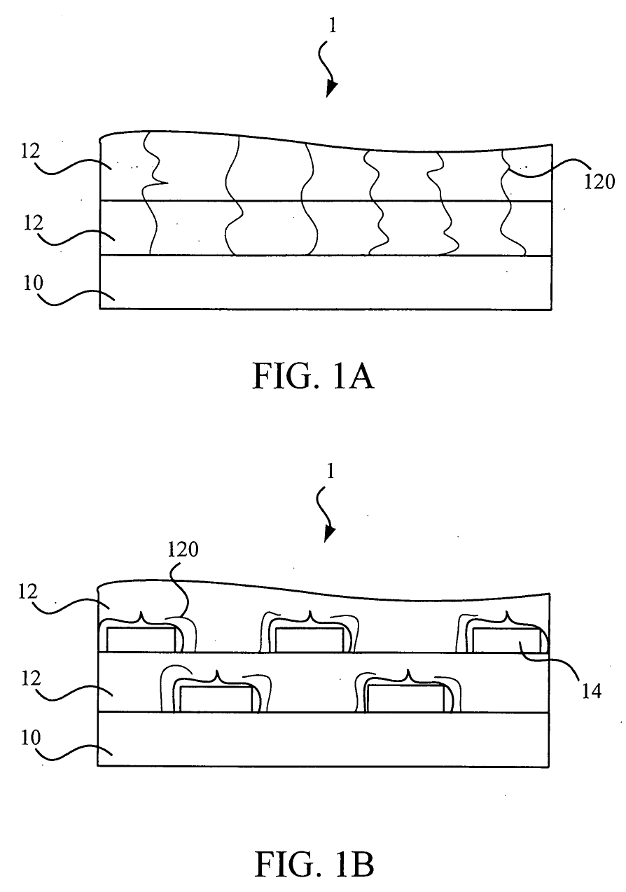

### DETAILED DESCRIPTION OF THE INVENTION

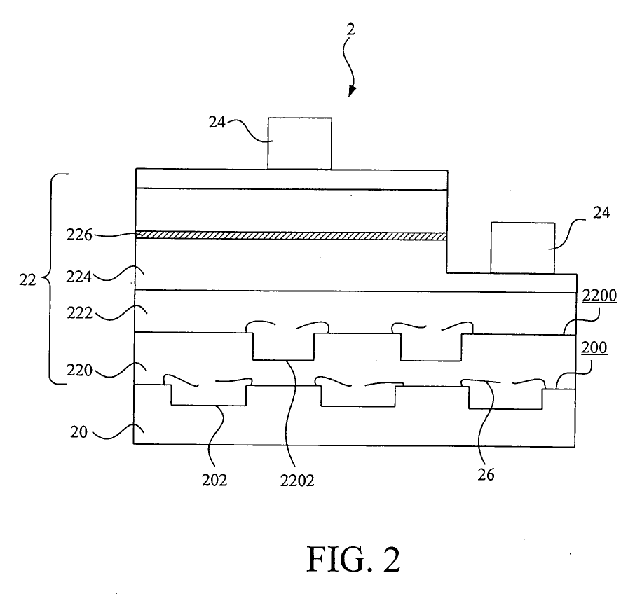

Please refer to FIG. 2. FIG. 2 is a sectional view of a semiconductor light-emitting device 2 according to an embodiment of the invention.

As shown in FIG. 2, the semiconductor light-emitting device 2 includes a substrate 20, a multi-layer structure 22, and an ohmic electrode structure 24.

In practical applications, the substrate 20 can be SiO₂, Si, Ge, GaN, AlN, sapphire, spinner, SiC, ZnO, MgO, GaAs, GaP, Al₂O₃, LiGaO₂, LiAlO₂, and MgAl₂O₄.

The substrate 20 has a first upper surface 200 and a plurality of first recesses 202 formed on the first upper surface 200. The multi-layer structure 22 is formed on the first upper surface 200 of the substrate 20 and includes a light-emitting region 226. A bottom-most layer 220 of the multi-layer structure 22 is formed on the first upper surface 200 of the substrate 20 and has a second upper surface 2200 and a plurality of second recesses 2202. The plurality of second recesses 2202 are formed on the second upper surface 2200 and project on the first upper surface 200 of the substrate 20. The ohmic electrode structure 24 is formed on the multi-layer structure 22.

In practical applications, the bottom-most layer 220 of the multi-layer structure 22 can be formed of a semiconductor material. In one embodiment, the semiconductor material can be an III-V group compound semiconductor material. An III group chemical element in the III-V group compound semiconductor material can be Al, Ga or In. A V group chemical element in the III-V group compound semiconductor material can be N, P, or As. In the embodiment, the semiconductor material can be GaN.

In one embodiment, both the plurality of first recesses 202 and the plurality of second recesses 2202 can be formed by a dry etching process or a wet etching process. For example, the dry etching process can be an inductive coupling plasma etching process.

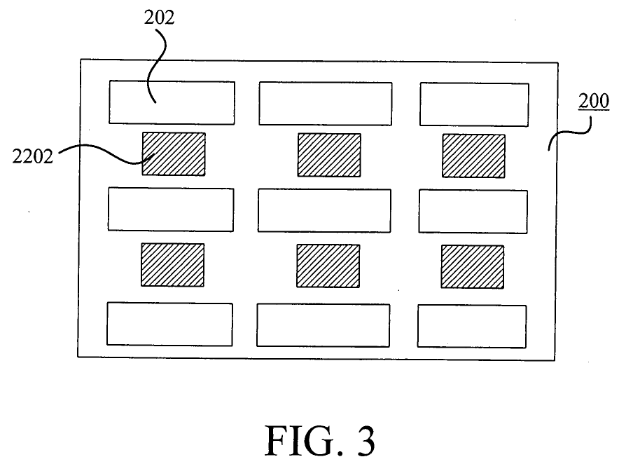

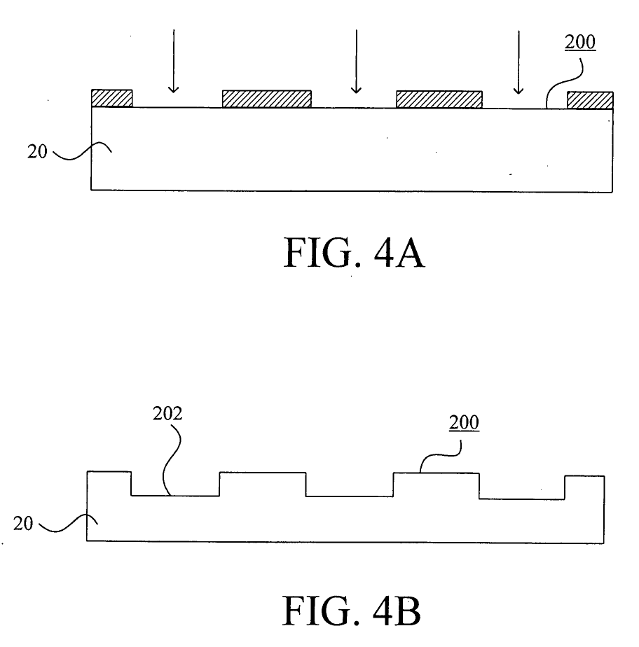

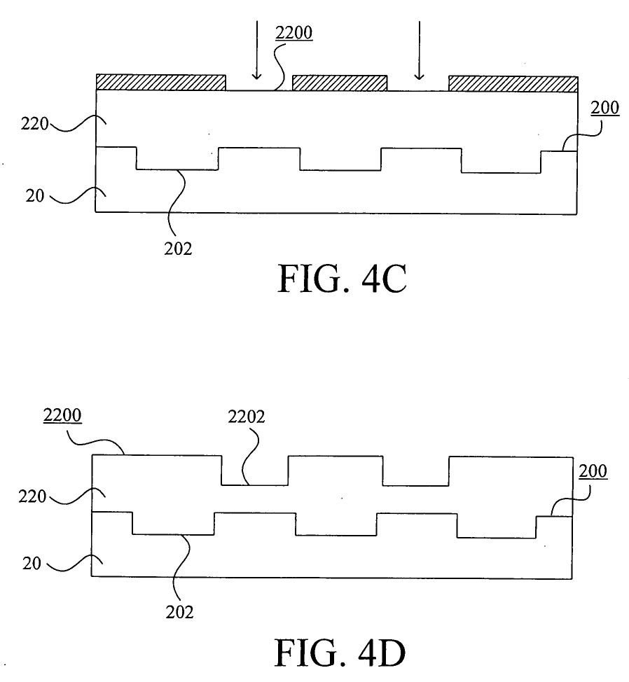

Please refer to FIG. 3. FIG. 3 is a projection view of the first recesses 202 and the second recesses 2202 on the first upper surface 200 of the substrate 20. As shown in FIG. 3, in a preferred embodiment, the plurality of second recesses 2202 can project on flat regions of the first upper surface 200 rather than the first recesses 202. In practical applications, the plurality of second recesses 2202 can project on flat regions and/or the first recesses 202 of the first upper surface 200.

Please refer to FIG. 2 again. The formations of the plurality of first recesses 202 and the plurality of second recesses 2202 can alter an air flow inside the semiconductor light-emitting device 2 to prohibit the inner defects 26 (e.g. dislocations) inside the semiconductor light-emitting device 2 form extending upward. Because the epitaxy needs to be performed on sufficient flat surfaces, sufficient flat surfaces in the first upper surface 200 of the substrate 20 are required.

After the bottom-most layer 220 of the multi-layer structure 22 is formed on the first upper surface 200 of the substrate 20, the plurality of second recesses 2202 formed on the second upper surface 2200 of the bottom-most layer 220 can be designed such that the plurality of first recesses 202 and the plurality of second recesses 2202 can be staggered in the vertical direction as the projection view on the first upper surface 200 shows in FIG. 3. Afterward, a bottom-next layer 222 of the multi-layer structure 22 can be formed on the bottom-most layer 220. In practical applications, the bottom-next layer 222 can be a GaN semiconductor material. Therefore, the plurality of second recesses 2202 can further prohibit the inner defects 26, not inhibited by the plurality of first recesses 202, inside the semiconductor light-emitting device 2 form extending upward.

After the growth directions of the inner defects 26 inside the semiconductor light-emitting device 2 are substantially altered in the bottom-most layer 220 and bottom-next layer 222, a semiconductor material layer 224 (e.g. GaN) can be formed on the bottom-next layer 222. Thereby, the semiconductor material layer 224 has the quality of low-density defects 26. Thus, the semiconductor light-emitting device 2 of low-density defects 26 can be formed by epitaxy on the semiconductor material layer 224 of low-density defects 26, and the inner quantum efficiency and light-extraction efficiency of the semiconductor light-emitting device 2 can be enhanced effectively.

In one embodiment, the substrate 20 can be SiO₂, Si, Ge, GaN, GaAs, GaP, AlN, sapphire, SiC, ZnO, MgO, LiGaO₂, and LiAlO₂.

The semiconductor light-emitting device 2 grown on the foregoing substrate 20 can form a semiconductor light-emitting device 2 with electrodes on an upper surface and a lower surface, i.e. an In-GaAlP LED. In other words, electrodes of the semiconductor light-emitting device 2 according to the invention are not limited to be formed on a same surface.

Please refer to the figures from FIG. 4A to FIG. 4F together with FIG. 2. The figures from FIG. 4A to FIG. 4F are the sectional views illustrating a method of fabricating a semiconductor light-emitting device 2 according to another embodiment of the invention.

First, as shown in FIG. 4A, the method prepares a substrate 20 and applies a first selective etching process on a first upper surface 200 of the substrate 20.

As shown in FIG. 4B, by the first selective etching process, a plurality of first recesses 202 are formed on the first upper surface 200.

Then, as shown in FIG. 4C, the method forms a bottom-most layer 220 of a multi-layer structure 22 on the first upper surface 200 of the substrate 20 and applies a second selective etching process on a second upper surface 2200 of the bottom-most layer 220.

As shown in FIG. 4D, by the second selective etching process, a plurality of second recesses 2202 are formed on the second upper surface 2200. The plurality of second recesses 2202 project on the first upper surface 200. In a preferred embodiment, the plurality of second recesses 2202 can project on flat regions of the first upper surface 200 rather than the first recesses 202.

Subsequently, as shown in FIG. 4E, the method forms other layers of the multi-layer structure 22 on the second upper surface 2200 of the bottom-most layer 220. The multi-layer structure 22 includes a light-emitting region 226.

Finally, as shown in FIG. 4F, the method forms an ohmic electrode structure 24 on the multi-layer structure 22 to finish the semiconductor light-emitting device 2.

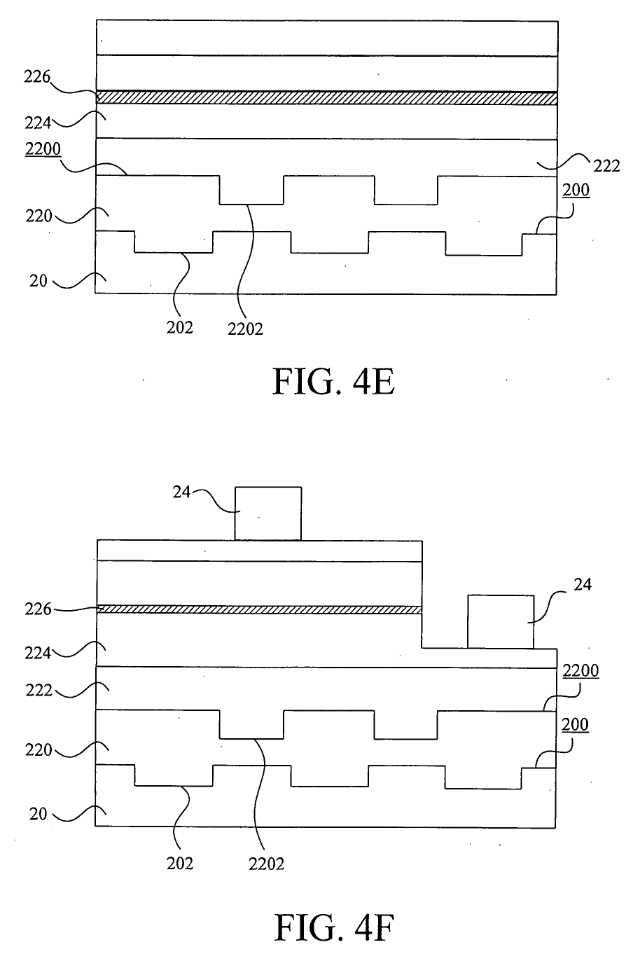

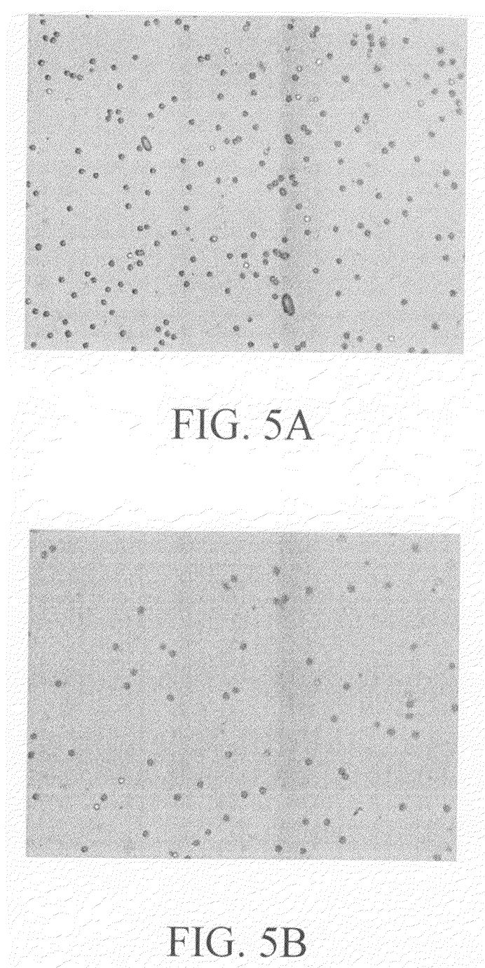

Please refer to FIG. 5A and FIG. 5B. FIG. 5A and FIG. 5B show the densities of inner defects 26 of an ordinary semiconductor light-emitting device and a semiconductor light-emitting device 2 according to the invention, respectively. FIG. 5A and FIG. 5B are obtained from the upper surface of the GaN material layer by an optical microscope. Dots in FIG. 5A and FIG. 5B represent the defects 26 (i.e. pits).

As shown in FIG. 5B, the density of inner defects 26 of the semiconductor light-emitting device 2 according to the invention is indeed much lower than that of an ordinary semiconductor light-emitting device by about 10-100 times, proving that the formations of the plurality of first recesses 202 and the plurality of second recesses 2202 can indeed improve the density of inner defects 26 of the semiconductor light-emitting device 2 according to the invention.

Compared to the prior art, the semiconductor light-emitting device according to the invention can have a semiconductor material layer with defects in low density, and the epitaxy of the semiconductor light-emitting device is to be performed on the semiconductor material layer. Thereby, the internal quantum efficiency and light-extraction efficiency of the semiconductor light-emitting device are enhanced. In addition, there is no contamination generated during the manufacturing process of the semiconductor light-emitting device according to the invention. Also, no haze phenomenon occurs on the surface of the semiconductor material layer.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

1. A semiconductor light-emitting device, comprising:
a substrate having a first upper surface and a plurality of first recesses formed in the first upper surface;
a multi-layer structure being formed on the first upper surface of the substrate and comprising a light-emitting region, a bottom-most layer of the multi-layer structure being formed on the first upper surface of the substrate and having a second upper surface and a plurality of second recesses, formed in the second upper surface, projecting on the first upper surface of the substrate; and
an ohmic electrode structure formed on the multi-layer structure.

2. The semiconductor light-emitting device of claim 1, wherein the plurality of second recesses further project on flat regions of the first upper surface rather than the first recesses.

3. The semiconductor light-emitting device of claim 1, wherein a bottom-next layer and the bottom-most layer of the multi-layer structure both are formed of a semiconductor material.

4. The semiconductor light-emitting device of claim 3, wherein the semiconductor material is a III-V group compound semiconductor material, a III group chemical element in the III-V group compound semiconductor material is one selected from the group consisting of A1, Ga and In, a V group chemical element in the III-V group compound semiconductor material is one selected from the group consisting of N, P, and As.

5. The semiconductor light-emitting device of claim 1, wherein the plurality of first recesses are formed by a dry etching process ora wet etching process.

6. The semiconductor light-emitting device of claim 1, wherein the plurality of second recesses are formed by a dry etching process or a wet etching process.

7. The semiconductor light-emitting device of claim 1, wherein the substrate is formed of a material selected from the group consisting of SiO₂, Si, Ge, GaN. AIN, sapphire, spinnel, SiC, ZnO, MgO, GaAs, GaP, A1₂O₃, LiGaO₂, LiA1O₂, and MgAI₂O₄.

8. A method of fabricating a semiconductor light-emitting device, said method comprising the steps of:
preparing a substrate;
applying a first selective etching process on a first upper surface of the substrate such that a plurality of first recesses are formed in the first upper surface;
forming a bottom-most layer of a multi-layer structure on the first upper surface of the substrate;
applying a second selective etching process on a second upper surface of the bottom-most layer such that a plurality of second recesses are formed in the second upper surface, wherein the plurality of second recesses project on the first upper surface of the substrate;
forming other layers of the multi-layer structure on the second upper surface of the bottom-most layer, wherein the multi-layer structure comprises a light-emitting region; and
forming an ohmic electrode structure on the multi-layer structure to finish said semiconductor light-emitting device.

9. The method of claim 8, wherein the plurality of second recesses further project on flat regions of the first upper surface rather than the first recesses.

10. The method of claim 8, wherein a bottom-next layer and the bottom-most layer of the multi-layer structure both are formed of a semiconductor material.

11. The method of claim 10, wherein the semiconductor material is a III-V group compound semiconductor material, a III group chemical element in the III-V group compound semiconductor material is one selected from the group consisting of AI, Ga and In; a V group chemical element in the III-V group compound semiconductor material is one selected from the group consisting of N, P, and As.

12. The method of claim 8, wherein the first selective etching process is a selective dry etching process or a selective wet etching process.

13. The method of claim 8, wherein the second selective etching process is a selective dry etching process or a selective wet etching process.

14. The method of claim 8, wherein the substrate is formed of a material selected from the group consisting of SiO₂, Si. Ge, CaN, AIN, sapphire, spinnel, SiC, ZnO, MgO, GaAs, GaP, A1₂O₃, LiGaO₂, LiAIO₂, and MgAI₂O₄.
